(19) United States
(12) Patent Application Publication
(10) Pub. No.: US 2013/0148277 A1
(43) Pub. Date: Jun. 13, 2013

(54) ELECTRONIC DEVICE

(71) Applicant: LG ELECTRONICS INC., Seoul (KR)

(72) Inventors: Choonghwan Shin, Seoul (KR); Kyoungsoo KANG, Seoul (KR)

(73) Assignee: LG ELECTRONICS INC., Seoul (KR)

(21) Appl. No.: 13/664,298

(22) Filed: Oct. 30, 2012

(30) Foreign Application Priority Data
Dec. 9, 2011 (KR) 10-2011-0131782

(51) Int. Cl. H05K 5/06; H05K 13/00

(52) U.S. Cl. 361/679.01; 29/592.1

(57) ABSTRACT

Provided is an electronic device. The electronic device include a first panel having a first surface, a second surface facing the first surface, and a hole connecting the first surface to the second surface, a sealing member passing through the hole, the sealing member being exposed to the first and second surfaces, and a second panel coupled to the first or second surface, the second panel contacting the exposed portion of the sealing member.

### CROSS-REFERENCE TO RELATED APPLICATIONS

The present application claims the benefit of earlier filing date and right of priority to Korean Patent Application No. 10-2011-0131782 filed on Dec. 9, 2011, which is herein incorporated by reference in its entirety.

### RELATED ART

The present disclosure relates to an electronic device.

Terminals belonging to electronic devices may be classified into mobile/portable terminal devices and stationary terminal devices according to whether they are movable. The mobile/portable terminal devices may be classified into hand-held terminal devices and floor-typed terminal devices according to whether they are directly portable by a user.

As the functional diversification of such a terminal, the terminal is being realized as a multimedia player form having a multiple functions such as photograph of pictures or moving images, decoding of music or moving image files, games, broadcast reception, and the like.

Electronic devices are built in the terminal. If the electronic devices contacts moisture, malfunction may occur. Thus, a sealing member for preventing moisture from being introduced may be provided in the terminal. For example, the sealing member may be disposed between a front case and a rear case which define an outer appearance of the terminal. In addition, the sealing member may be disposed between the rear case and a battery case mounted on a rear side of the rear case.

In case of a terminal according to a related art, the sealing member is separately manufactured and then disposed and coupled on a portion at which a waterproof structure is required when the terminal is assembled. Here, if the sealing member is manufactured using a material having low hardness, i.e. a flexible material, since the sealing member has a high adhesion force, the sealing member may be closely coupled to components contacting the sealing member. However, when assembled, it may be difficult to locate and couple the sealing member within the electronic device. On the other hand, if the sealing member is manufactured using a material having high hardness, the sealing member may be easily assembled with the terminal when assembled. However, adhesion forces between the sealing member and other components are low. Thus, the sealing member does not closely adhere to the other components to reduce the finishability of products.

### SUMMARY

Embodiments provide a waterproof structure of a terminal device in which a sealing member coupling structure is improved to increase an adhesion force with other components and improve assemblability.

In one embodiment, an electronic device includes: a first panel having a first surface, a second surface facing the first surface, and a hole connecting the first surface to the second surface; a sealing member passing through the hole, the sealing member being exposed to the first and second surfaces; and a second panel coupled to the first or second surface, the second panel contacting the exposed portion of the sealing member.

The details of one or more embodiments are set forth in the accompanying drawings and the description below. Other features will be apparent from the description and drawings, and from the claims.

### BRIEF DESCRIPTION OF THE DRAWINGS

FIG. 1 is a perspective view illustrating an outer appearance of an electronic device according to an embodiment.

FIG. 2 is a rear perspective view of the electronic device of FIG. 1.

FIG. 3 is a perspective view of a rear case of the electronic device from which a sealing member is removed.

FIG. 4 is a cross-sectional view taken along line A-A′ of FIG. 3.

FIG. 5 is a cross-sectional view taken along line B-B′ of FIG. 3.

FIGS. 6 and 7 are views of the rear case in which the sealing member is disposed according to an embodiment.

FIG. 8 is a partially cross-sectional view of the rear case on which a battery case is mounted according to an embodiment.

### DETAILED DESCRIPTION OF THE EMBODIMENTS

In the following detailed description of the preferred embodiments, reference is made to the accompanying drawings that form a part hereof, and in which is shown by way of illustration specific preferred embodiments in which the invention may be practiced. These embodiments are described in sufficient detail to enable those skilled in the art to practice the invention, and it is understood that other embodiments may be utilized and that logical structural, mechanical, electrical, and chemical changes may be made without departing from the spirit or scope of the invention. To avoid detail not necessary to enable those skilled in the art to practice the invention, the description may omit certain information known to those skilled in the art. The following detailed description is, therefore, not to be taken in a limiting sense, and the scope of the present invention is defined only by the appended claims.

A terminal described in the present specification may be applied to mobile/portable terminal devices such as mobile phones, smart phones, laptop computers, digital broadcasting terminals, personal digital assistants (PDAs), portable multimedia players (PMPs), navigations, and the like, as well as, stationary terminal devices such as digital televisions, desktop computers, and the like.

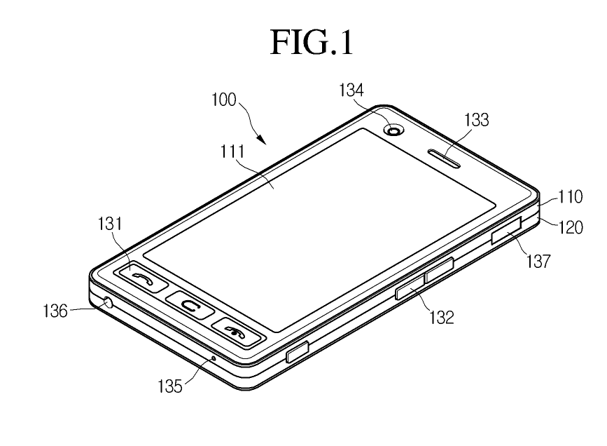

FIG. 1 is a perspective view illustrating an outer appearance of an electronic device according to an embodiment.

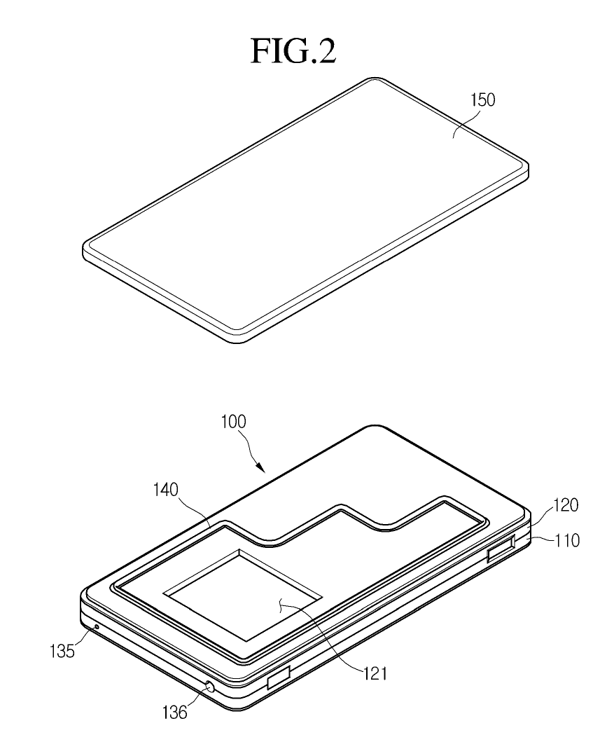

Referring to FIG. 1, an electronic device 100 according to an embodiment includes a case defining an outer appearance thereof. The case includes a front case 110 disposed on a front portion of the electronic device 100 and a rear case 120 disposed on a rear portion of the electronic device 100. A battery case (see reference number 150 of FIG. 2) may be additionally provided on a rear portion of the rear case 120. At least one frame is disposed between the front case 110 and the rear case 120. A variety of electronic components are built in a space defined between the front case 110 and the rear case 120. The case or frame may be injection-molded using a synthetic resin or manufactured using a metal material such as stainless steel (STS) or titanium (Ti).

A display unit 111, user input units 131 and 132, an acoustic output unit 133, a camera 134, a microphone 135, an antenna 136, and an interface 137 may be disposed on front and lateral surfaces of the electronic device 100 constituted by the front case 110 and the rear case 120.

In detail, the display unit 111 occupies most of the front surface of the front case 110. The acoustic output unit 133 and the camera 134 are disposed on an area adjacent to one end of both ends of the display unit 111. The first manipulating unit 131 that is one of the user input units, the microphone 135, and the antenna 136 are disposed on an area adjacent to the other end of both ends of the display unit 111. The second manipulating unit 132 and the interface 170 may be disposed on the lateral surface of the electronic device 100.

The user input units 131 and 132 are provided to input a command for controlling an operation of the electronic device 100. The user input units 131 and 132 may include the plurality of manipulating units 131 and 132. The manipulating units 131 and 132 may be commonly called a manipulating portion. Also, if a tactile manner in which the manipulating portion is manipulated through user's tactile stimuli is enabled, any manner may be adopted for the manipulating portion. Contents inputted by the manipulating portion may be variously set. For example, the first manipulating unit 131 may input commands such as an ON/OFF command of the electronic device 100 and starting, ending, and scrolling commands for a program inputted into the electronic device 100. The second manipulating unit 132 may input commands such as a command for adjusting the level of a sound outputted from the acoustic output unit 133 and a conversion command into a touch recognition mode of the display unit 111. Also, the antenna 136 for receiving broadcasting signals in addition to an antenna for calling and the like may be additionally disposed withdrawable from the electronic device 100 on the lateral surface of the electronic device 100.

Although the disclosed electronic device 100 includes an electronic device body having a bar shape, the present disclosure is not limited to the bar shape. For example, the electronic device body may have various structures such as a slide type, a fold type, a swing type, a swivel type, and the like.

FIG. 2 is a rear perspective view of the electronic device of FIG. 1.

Referring to FIG. 2, the battery case 150 may be disposed on the rear portion of the rear case 120. A battery insertion part 121 in which a battery is insertable is provided in the rear case 120. After the battery is mounted into the battery insertion part 121, the battery case 150 is coupled to the rear potion of the rear case 120 to prevent the battery from being separated from the battery insertion part 121. In case where it is required to replace the battery, a user can detach the battery after the battery case 150 is separated from the electronic device 100.

A sealing member 140 is disposed on a rear surface of the rear case 120. The sealing member 140 may protrude from the rear surface of the rear case 120. When the battery case 150 is mounted on the rear portion of the rear case 120, the sealing member 140 contacts an inner side surface of the battery case 150 to prevent moisture from being permeated between the battery case 150 and the rear case 120. The sealing member 140 may be manufactured in an adequate shape so that the moisture is not permeated into the electronic device 100. For example, the sealing member 140 may have a close loop shape surrounding the battery insertion part 121. Thus, it may prevent the moisture from being introduced into the battery insertion part 121.

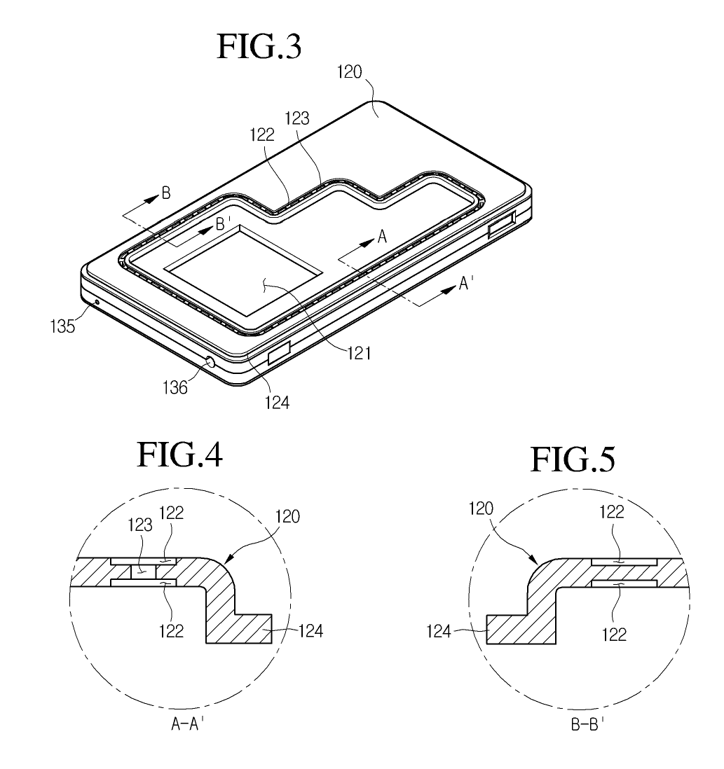

FIG. 3 is a perspective view of a rear case of the electronic device from which a sealing member is removed. FIG. 4 is a cross-sectional view taken along line A-A′ of FIG. 3. FIG. 5 is a cross-sectional view taken along line B-B′ of FIG. 3.

Referring to FIGS. 3 to 5, a sealing member receiving groove 122 in which the sealing member 140 is mounted is provided in the rear case 120. The sealing member receiving groove 122 may be adequately provided according to a position at which the sealing member 140 is required or a shape of the sealing member 140. For example, the sealing member receiving groove 122 may have a close loop shape surrounding the battery insertion part 121. The sealing member receiving groove 122 may be provided in each of top and bottom surfaces of the rear case 120.

Also, a hole 123 passing through the rear case 120 may be defined in the sealing member receiving groove 122. The hole 123 may have a width less than that of the bottom of the sealing member receiving groove 122.

Referring to FIG. 4, the sealing member receiving groove 122 defined in each of the top and bottom surfaces of the rear case 120 may communicate with each other through the hole 123. That is, a section defined by the sealing member receiving groove 122 and the hole 123 may have a “I” shape. Also, the hole 123 may be provided in plurality. The plurality of holes 123 may be defined with a certain distance in the sealing member receiving groove 122. Thus, as shown in FIG. 5, the sealing member receiving grooves 122 defined in the top and bottom surfaces of the rear case 120 do not communicate with each other between the holes 123 adjacent to each other.

The sealing member receiving groove 122 may be provided in a position corresponding to each of the top and bottom surfaces of the rear case 120. The sealing member receiving grooves 122 defined in the top and bottom surfaces of the rear case 120 may have the same shape or different shapes. For example, the bottom of the sealing member receiving groove 122 defined in one of the top and bottom surfaces of the rear case 120 may have a width greater or less than that of the sealing member receiving groove 122 defined in the other one of the top and bottom surfaces of the rear case 120. The sealing member receiving grooves 122 may have depths different from each other.

Also, the sealing member receiving groove 122 defined in one of the top and bottom surfaces of the rear case 120 may have a close loop shape continuously disposed along an edge of the battery insertion part 121. The sealing member receiving groove 122 defined in the other one of the top and bottom surfaces of the rear case 120 may be defined along the edge of the battery insertion part 121. Here, a plurality of short grooves may be discontinuously defined spaced apart from each other with a predetermined distance. Also, the bottom of the sealing member receiving grooves 122 may have a width greater than that of the hole 123.

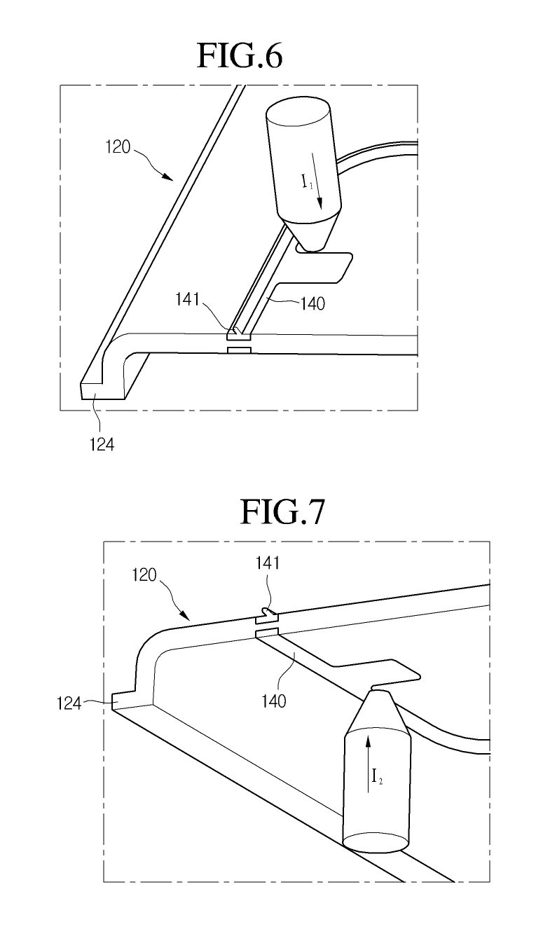

FIGS. 6 and 7 are views of the rear case in which the sealing member is disposed according to an embodiment.

Referring to FIGS. 6 and 7, the sealing member 140 may be insert-injected into the rear case 120. In detail, the rear case 120 having the sealing member receiving groove 122 in the top and bottom surface thereof may be disposed on a mold, and then, a resin for forming the sealing member 140 may be injected into the sealing member receiving groove 122 through injection gates I1 and I2 to form the sealing member 140 fixed to the rear case 120.

Here, since the sealing member receiving grooves 122 defined in both surfaces of the rear case 120 communicate with each other by the hole 123, the resin may be injected through one of the injection gates I1 and I2 disposed in the top and bottom surfaces of the rear case 120 or all of the injection gates I1 and I2. That is, when a material for sealing member 140 is injected through the gate I2 disposed in one side of the rear case 120, the material for sealing member 140 may be injected into the sealing member receiving groove 122 defined in the other side of the rear case 120 through the hole 123. On the other hand, when the material for sealing member 140 is injected into the other gate I1 of the rear case 120, the material for sealing member 140 may be injected into the sealing member receiving groove 122 defined in one side of the rear case 120. Since the material is injected, the sealing member 140 may have a shape corresponding to those of the sealing member receiving groove 122 and the hole 123. As a result, the sealing member 140 is closely coupled to the rear case 120. Also, the sealing member 140 disposed on outer and inner surfaces of the rear case 120 may be integrally connected through the hole 123.

In case where the sealing member 140 is provided as described above, a separate process for fitting the sealing member 140 into the rear case 120 is not required. Thus, even though the sealing member 140 is formed of a material having low hardness, the sealing member 140 may be completely attached to the rear case 120. Also, since the material for sealing member 140 may be injected through the front or rear side of the rear case 120, the sealing member 140 may be easily assembled, and also, assembly lines for the sealing member 140 may be conveniently constructed.

The sealing member 140 includes a protrusion 141 protruding from at least one surface of the rear case 120. The protrusion 141 protruding from the top surface of the rear case 120 closely contacts the battery case 150 mounted on the rear portion of the rear case 120. Also, the battery case 150 presses the protrusion 141 disposed on the rear portion of the rear case 120. The protrusion 141 is disposed on a position corresponding to that of the sealing member insertion groove 122. Also, the protrusion 141 may be a shape adequate for preventing moisture from being permeated into the electronic device 100. For example, the protrusion 141 may have a close loop shape extending along an edge of the sealing member insertion groove 122. Also, the protrusion 141 may be inclined toward the outside of the rear case 120. When the protrusion 141 is pressed by the battery case 150, an end of the protrusion 141 may face the outside of the rear case 120. Due to the above-described structure of the protrusion 141, the protrusion 141 may more completely prevent the moisture from being permeated when compared to a case in which the protrusion 141 vertically extends or is inclined toward a center of the rear case 120.

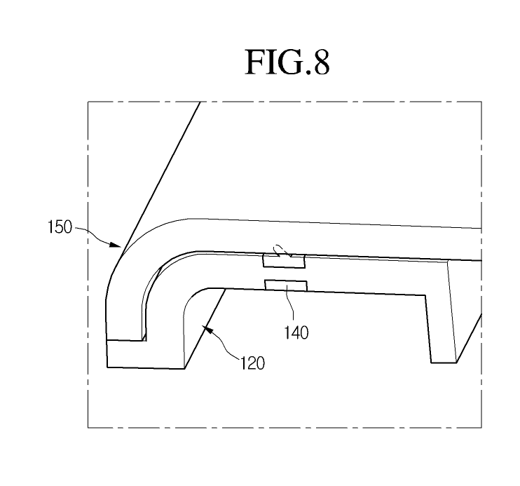

FIG. 8 is a partially cross-sectional view of the rear case on which a battery case is mounted according to an embodiment.

Referring to FIG. 8, it may prevent moisture from being permeated into the battery insertion part 121 due to the sealing member 140 disposed between the battery case 150 and the rear case 120. In detail, the inner surface of the battery case 150 presses the protrusion 141 of the sealing member 140 to prevent the moisture from being permeated between the battery case 150 and the rear case 120. Also, since the protrusion 141 is pressed toward the outside of the rear case 120, moisture the permeation prevention effect may be further improved.

The sealing member 140 may be manufactured using the material having low hardness to increase the adhesion force with other members. Also, since the sealing member 140 is insert-injected, the sealing member 140 may be closely coupled to the rear case 120 to significantly improve the waterproof performance.

Although the sealing member 140 is disposed on the rear case 120 of the electronic device 100 to prevent moisture from being permeated between the rear case 120 and the battery case 150, the present disclosure is not limited to the device and components in relation to the structure in which the sealing member is provided through the insert-injection. The configuration with respect to the sealing member manufactured through the insert-injection may be applied to any device if the waterproof structure is required.

For example, in the electronic device such as the terminal device, the sealing member may be realized on one of first and second panels through the above-described method to prevent moisture from being permeated through a gap defined between the first and second panels. In the embodiment related to the electronic device 100, one of the rear case 120 and the battery case 150 may be referred to as the first panel, and the other one may be referred to as the second panel.

Also, the shape of the sealing member is not limited to the above-described shape. For example, the sealing member may be realized as the close loop shape or a shape similar to the protrusion.

According to the waterproof structure of the electronic device, the assemblability of the sealing member may be improved, and the adhesion force with other components may be increased to improve the waterproof performance.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An electronic device comprising:
a first panel having a first surface, a second surface that faces the first surface and at least one hole connecting the first surface to the second surface;
a sealing member passing through the at least one hole such that the sealing member is exposed to the first and second surfaces; and
a second panel coupled to the first or second surface such that the second panel contacts an exposed portion of the sealing member.

2. The electronic device according to claim 1, further comprising:
a receiving groove in which the sealing member is located, the receiving groove defined in each of the first and second surfaces,
wherein the at least one hole passes through a bottom portion of the receiving groove.

3. The electronic device according to claim 2, wherein the receiving groove defined in the first surface has a same width as the receiving groove defined in the second surface.

4. The electronic device according to claim 2, wherein the receiving groove defined in the first surface has a different width different than the receiving groove defined in the second surface.

5. The electronic device according to claim 2, wherein the receiving groove defined in the first surface has a same depth as the receiving groove defined in the second surface.

6. The electronic device according to claim 2, wherein the receiving groove defined in the first surface has a different depth different than the receiving groove defined in the second surface.

7. The electronic device according to claim 2, wherein a plurality of holes are provided at a bottom surface of the receiving groove.

8. The electronic device according to claim 7, wherein the receiving groove defined in each of the first and second surfaces has a continuous closed-loop shape.

9. The electronic device according to claim 7, wherein:
the receiving groove defined in one of the first and second surfaces has a continuous closed-loop shape; and
the receiving groove defined in the other of the first and second surfaces is spaced a predetermined distance from the receiving groove defined in the one of the first and second surfaces and located such that it is spaced apart by a predetermined distance from the receiving groove defined in the one of the first and second surfaces.

10. The electronic device according to claim 9, wherein the receiving groove having the continuous closed-loop shape is defined in the first or second surface that is coupled to the second panel.

11. The electronic device according to claim 2, wherein the sealing member comprises a flexible injection-molded material via which a resin is injected into at least the first or second surface.

12. The electronic device according to claim 2, further comprising a protrusion, the protrusion located on an outer surface of the sealing member that contacts and is pressed by the second panel.

13. The electronic device according to claim 12, wherein the protrusion is inclined at a predetermined angle.

14. The electronic device according to claim 12, wherein the protrusion is inclined toward an outer edge of the first panel.

15. A method of protecting an electronic device against moisture, the method comprising:
providing a first panel having a first surface, a second surface that faces the first surface and at least one hole connecting the first surface to the second surface;
providing a sealing member that passes through the at least one hole such that the sealing member is exposed to the first and second surfaces; and
providing a second panel that is coupled to the first or second surface such that the second panel contacts an exposed portion of the sealing member.

16. The method according to claim 15, further comprising:
providing a receiving groove that is defined in each of the first and second surfaces such that the at least one hole passes through a bottom portion of the receiving groove; and
disposing the sealing member in the receiving groove.

17. The method according to claim 16, further comprising providing a plurality of holes at a bottom surface of the receiving groove and wherein:
the receiving groove defined in one of the first and second surfaces has a continuous closed-loop shape; and
the receiving groove defined in the other of the first and second surfaces is spaced a predetermined distance from the receiving groove defined in the one of the first and second surfaces and located such that it is spaced apart by a predetermined distance from the receiving groove defined in the one of the first and second surfaces by a predetermined distance.

18. The method according to claim 17, wherein the receiving groove having the continuous closed-loop shape is defined in the first or second surface that is coupled to the second panel.

19. The method according to claim 16, wherein the sealing member comprises a flexible injection-molded material and further comprising injecting a resin into at least the first or second surface.

20. The method according to claim 16, further comprising providing a protrusion, the protrusion located on an outer surface of the sealing member that contacts the second panel and is pressed by the second panel.
